(19) United States
(12) Patent Application Publication
(10) Pub. No.: US 2025/0029924 A1
(43) Pub. Date: Jan. 23, 2025

(54) CORRUGATED TIER SUPPORT STRUCTURE AND REPLACEMENT SOURCE INTERIOR CHANNEL POLY METALIZED LATERAL CONTACT FLOW

(71) Applicant: Micron Technology, Inc., Boise, ID (US)

(72) Inventors: Darwin A. Clampitt, Wilder, ID (US); Roger W. Lindsay, Boise, ID (US)

(21) Appl. No.: 18/772,808

(22) Filed: Jul. 15, 2024

Related U.S. Application Data
(60) Provisional application No. 63/527,475, filed on Jul. 18, 2023.

(51) Int. Cl. H01L 23/528; H01L 23/522; H10B 41/10; H10B 41/27; H10B 41/35; H10B 43/10; H10B 43/27; H10B 43/35

(52) U.S. Cl. CPC H01L 23/5283; H01L 23/5226; H01L 23/528; H10B 41/10; H10B 41/27; H10B 41/35; H10B 43/10; H10B 43/27; H10B 43/35

(57) ABSTRACT

A semiconductor device, such as comprising NAND memory structures, can include a substrate with an arrangement of conductive interconnects. A corrugated support can be provided on the substrate, wherein the support comprises a planar first major surface and an opposed second major surface proximal to the substrate, the first major surface including a plurality of vias extending along a first direction, wherein the vias have an inlet at a first major surface of the support and an outlet at the second major surface of the support. An arrangement of flutes can be provided on the second major surface of the support. The flutes can extend along a second direction normal to the first direction. The flutes are separated by voids, and the vias terminate in the voids.

### PRIORITY APPLICATION

This application claims the benefit of priority to U.S. Provisional Application Ser. No. 63/527,475, filed Jul. 18, 2023, which is incorporated herein by reference in its entirety.

### BACKGROUND

Memory devices are provided as internal, semiconductor integrated circuits in computers or other electronic devices. Flash memory is utilized as non-volatile memory for a wide range of electronic applications. The memory density (e.g., the number of memory cells per memory die) of memory devices, such as non-volatile memory devices (e.g., NAND Flash memory devices) has been increased through implementation of vertical memory array (also referred to as a “three-dimensional (3D) memory array”) architectures.

A conventional vertical memory array includes a plurality of memory cell pillars extending through tiers formed from a stack of alternating substantially planar layers of dielectric materials and conductive materials. The memory cell pillars include a channel region positioned between a source region and a drain region, and the conductive layers in the tiers function as control gates in the completed device. The vertical configuration permits a greater number of electrical components (e.g., transistors) to be located in a unit of die area by building the array upwards (e.g., longitudinally, vertically) on a die, as compared to structures with conventional planar (e.g., two-dimensional) arrangements of electrical components.

To form the channel regions of the memory cell pillars, a first etch process is conducted to create, through a deck of tiers of alternating dielectric and nitride structures, a tapered high aspect ratio opening along a direction normal to a plane of a the die or other support layer underlying the tier stack. The openings are subsequently filled with a conductive material to form the memory cell pillars, and the memory cell pillars are electrically connected with structures in the underlying die or support layer.

Increasing aspect ratios of the openings used to form the memory cell pillars, as well as increasing numbers of alternating dielectric and nitride layers in the stack, make precise control of the etch process increasingly difficult. The large number of layers in the stack also make formation of reliable electrical connections to the dies and support layers at the bottom of the openings increasingly challenging.

### BRIEF DESCRIPTION OF THE DRAWINGS

The drawings, which are not necessarily drawn to scale, illustrate generally, by way of example, but not by way of limitation, various embodiments discussed in the present document.

FIG. 1A is a schematic cross-sectional view of a workpiece suitable for use in the methods of the present disclosure for forming a cell in a memory cell array, according to various embodiments.

FIG. 1B is a schematic overhead view of the workpiece of FIG. 1A.

FIG. 2 is a schematic cross-sectional view of the example workpiece of FIG. 1A including a sacrificial oxide layer, according to various embodiments.

FIG. 3A is a schematic cross-sectional view of the workpiece of FIG. 2, including a patterned sacrificial oxide layer.

FIG. 3B is on schematic overhead view of the workpiece of FIG. 3A.

FIG. 4A is a schematic cross-sectional view of the workpiece of FIG. 3A-3B including a structural layer applied over the patterned sacrificial layer.

FIG. 4B is a schematic overhead view of the workpiece of FIG. 4A.

FIG. 4C is a view of the workpiece of FIG. 4B taken along line A-A in FIG. 4B.

FIG. 5A is a schematic cross-sectional view of the workpiece of FIGS. 4A-4C including channels suitable for forming an etch stop layer.

FIG. 5B is a schematic overhead view of the workpiece of FIG. 5A.

FIG. 6A is a schematic cross-sectional view of the workpiece of FIGS. 5A-5B including an array of apertures in the structural layer.

FIG. 6B is a schematic overhead view of the workpiece of FIG. 6A.

FIG. 7A is a schematic cross-sectional view of the workpiece of FIGS. 6A-6B including a sacrificial material in the apertures and channels.

FIG. 7B is a schematic overhead view of the workpiece of FIG. 7A.

FIG. 8 is a schematic cross-sectional view of the workpiece of FIGS. 7A-7B including a tier stack on the structural layer.

FIG. 9A is a schematic cross-sectional view of the workpiece of FIG. 8 including openings in the tier stack terminating in the apertures.

FIG. 9B is a view of the workpiece of FIG. 9A taken along a line B-B in FIG. 9A.

FIG. 10A is a schematic cross-sectional view of the workpiece of FIGS. 10A-10B including a channel poly layer in the openings and the cavities.

FIG. 10B is a schematic cross-sectional view of a section of the chanel poly layers in FIG. 10A.

FIG. 11 is a schematic cross-sectional view of the workpiece of FIG. 10A including pillars in the openings.

FIG. 12 is a schematic cross-sectional view of the workpiece of FIG. 11 including slits formed in the tier stack.

FIG. 13 is a schematic cross-sectional view of the workpiece of FIG. 12 in which the etch stop layer below the slits is removed.

FIG. 14 is schematic cross-sectional view of the workpiece of FIG. 13 including a nitride spacer layer in the slits.

FIG. 15 is a schematic cross-sectional view of the workpiece of FIG. 14 in which portions of the channel poly layers in the cavity and outlet regions of the apertures are removed.

FIG. 16 is a schematic cross-sectional view of the workpiece of FIG. 15 in which the oxide regions are removed from the contact regions of apertures.

FIG. 17 is a schematic cross-sectional view of the workpiece of FIG. 16 in which the conductive layers and oxide layers underlying the opening in the nitride spacers are removed such that the openings extend to the source lines.

FIG. 18 is a schematic cross-sectional view of the workpiece of FIG. 17 in which a conductive metal is deposited in the cavities and the outlet regions of the apertures.

FIG. 19 is a schematic cross-sectional view of the workpiece of FIG. 18 including a plug formed over the source fill lines.

FIG. 20 is a schematic cross-sectional view of the workpiece of FIG. 19 in which conductive metal is removed from below the nitride spacer in the slits.

FIG. 21 is a schematic cross-sectional view of the workpiece of FIG. 20 in which the nitride spacer is removed from the slits, and nitride layers are removed from the tiers.

FIG. 22 is a schematic cross-sectional view of the workpiece of FIG. 21 in which the slits are filled with a dielectric material, a conductive material, or a combination thereof.

FIG. 23 is a flow diagram of features of an example method of making the workpieces of the present disclosure, according to various embodiments.

FIG. 24 is a flow diagram of features of another example method of making the workpieces of the present disclosure, according to various embodiments.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

Like symbols in the drawings indicate like elements.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments.

The following description provides specific details, such as material types, material thicknesses, and process conditions to provide a thorough description of embodiments described herein. However, a person of ordinary skill in the art will understand that the embodiments disclosed herein may be practiced without employing these specific details, and the embodiments may be practiced in conjunction with conventional fabrication techniques employed in the semiconductor industry. In addition, the description provided herein does not form a complete description of a semiconductor device or a complete process flow for manufacturing the semiconductor device and the structures described below do not form a complete semiconductor device. Only those process acts and structures necessary to understand the embodiments described herein are described in detail below. Additional acts to form a complete semiconductor device may be performed by conventional techniques.

As used herein, the singular forms “a,” “an,” and “the” are intended to include the plural forms as well, unless the context clearly indicates otherwise.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “configured” refers to a size, shape, material composition, and arrangement of one or more of at least one structure and at least one apparatus facilitating operation of one or more of the structure and the apparatus in a pre-determined way.

As used herein, the term “pitch” refers to the distance between identical points in two adjacent (i.e., neighboring) features.

As used herein, the term “selectively etchable” means and includes a material that exhibits a greater etch rate responsive to exposure to a given etch chemistry relative to another material exposed to the same etch chemistry. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “semiconductor device” or “integrated circuit device” includes without limitation a memory device, as well as other semiconductor devices which may or may not incorporate memory, such as a logic device, a processor device, or a radiofrequency (RF) device. Further, a semiconductor device may incorporate memory in addition to other functions such as, for example, a so-called “system on a chip” (SoC) including a processor and memory, or a semiconductor device including logic and memory.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a base material or construction upon which additional materials are formed. The substrate may be a semiconductor substrate, a base semiconductor layer on a supporting structure, a metal electrode, or a semiconductor substrate having one or more materials, layers, structures, or regions formed thereon. The materials on the semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

As used herein, the term “exhume” refers to a selective etching step in which all or a portion of a first layer is etched from below a second layer overlying the first layer.

The materials described herein may be formed by conventional techniques including, but not limited to, spin coating, blanket coating, chemical vapor deposition (CVD), atomic layer deposition (ALD), plasma enhanced ALD, or physical vapor deposition (PVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

In general, the present disclosure is directed to a workpiece processable to form a semiconductor device, or a sub-component of a semiconductor device, that includes a corrugated support. The corrugated support, which resides on a substrate that includes conductive interconnect structures, includes a substantially planar first major surface configured to support one or more other layers or structures, such as a tier stack of alternating conductive and non-conductive layers, for example, dielectric layers and nitride layers. The corrugated support further includes a fluted second major surface between the first major surface and the substrate. Vias extending through the support are arranged to terminate in voids between flutes in the fluted surface. The flutes on each side of the vias provide structural support to a conductive structure terminating in the vias, and enhance the structural integrity of the workpiece.

In another aspect, the present disclosure is directed to methods in which the voids between the flutes in the corrugated support are filled with a conductive material to make contact between a channel poly layer terminating in a via and the interconnect structures in the underlying substrate. For example, a tier stack on the first major surface of the corrugated support can have a large number of alternating conductive and non-conductive layers, and tapered openings formed in the tiers have a small pitch and a large aspect ratio. Forming electrical connections between conductive layers in the tapered openings and the interconnect structures in the substrate below can be difficult. In the methods of the present disclosure, conductive materials in the voids are used to form electrical connections between the channel poly layers in the tapered openings and the interconnect structures in the underlying substrate. Since the tapered openings in the tiers extend along a first direction and the voids extend along a second direction normal to the first direction, electrical connections may be formed laterally with respect to the tapered openings, and can provide a more reliable electrical connection compared to electrical connections formed along the length of the tapered openings.

In another example, an arrangement of slits may be formed in areas of the tier stack, wherein the slits extend along a a third direction normal to the first direction of the tapered openings and the second direction of the voids. The slits may be filled with a conductive material to make electrical connections between the tiers and the interconnect structures in the underlying substrate, and the electrical connections thus formed do not necessitate forming connections to channel poly layers in individual tapered openings. In addition, the flutes in the corrugated support enhance the structural strength of the support when the slits are formed in the tiers.

The corrugated support of the present disclosure can provide enhanced structural strength to the semiconductor device including pillars formed in the tapered openings, and can enhance reliability of the electrical connections between the pillars and conductive elements in an underlying substrate. The corrugated support of the present disclosure can provide enhanced resistance to failure during downstream process steps such as, for example, during replacement of the layers of nitride materials in the tier stack with layers of conductive materials. In some examples, the reduced failure rates improve the quality of the semiconductor device and can reduce overall production costs.

In one aspect, the present disclosure is directed to a semiconductor device including a substrate with an arrangement of conductive interconnects, and a corrugated support on the substrate. The support includes a substantially planar first major surface and an opposed second major surface proximal to the substrate. The first major surface includes a plurality of vias extending along a first direction, wherein the vias have an inlet at a first major surface of the support and an outlet at the second major surface of the support. An arrangement of flutes is on the second major surface of the support, wherein the flutes extend along a second direction normal to the first direction, wherein the flutes are separated by voids, and wherein the vias terminate in the voids.

In another aspect, the present disclosure is directed to a method for making a semiconductor device. The method includes forming a substrate with an arrangement of conductive source lines; forming a support on the substrate, wherein the support has a first major surface and an opposed second major surface on the substrate, and wherein the second major surface of the support includes a cavity; and forming an arrangement of vias extending from the first major surface to the second major surface of the support, wherein the vias terminate in the cavity.

The method further includes depositing tiers including alternating dielectric layers and nitride layers on the first major surface of the support; and forming tapered openings in the tiers, wherein the openings extend in a first direction normal to a plane of the support, and wherein each of the openings terminates in an aperture in the support.

The method further includes depositing a channel poly material in the tapered openings to form a first channel poly layer on walls thereof and a second channel poly layer on walls of the cavity, wherein the first channel poly layer forms a plug in a region of the opening adjacent to the cavity; etching an arrangement of slits in the tiers, wherein the slits are aligned with the source lines in the substrate, and wherein the slits form access regions to the cavity; etching the first channel poly layer to remove the plug and the second channel poly layer; forming passages through the substrate to the source lines; and depositing a conductive material in the cavity and the passages to form an ohmic contact between the first channel poly layer and the source lines in the substrate.

After the electrical connections are formed between the first conductive layer in the tapered openings and the source lines in the substrate, the resulting workpiece may be utilized in a conventional manner to form a semiconductor device such as, for example, a vertically stacked NAND array. For example, the layers of the nitride materials in the tier stack are ultimately replaced by conductive materials to form control gates in the completed semiconductor device, and oxide materials are deposited in the tapered openings to form pillars. The method and workpiece of the present disclosure can thus provide a more repeatable process for forming the contacts to the conductive pillars that are formed in the tapered opening in downstream process steps. As the tapered openings become smaller and number of layers in the tier stack more numerous, the workpiece and process of the present disclosure can be used to manufacture a more reliable semiconductor device with increased data storage capacity.

Various embodiments of the method and workpieces of the present disclosure are discussed in detail below.

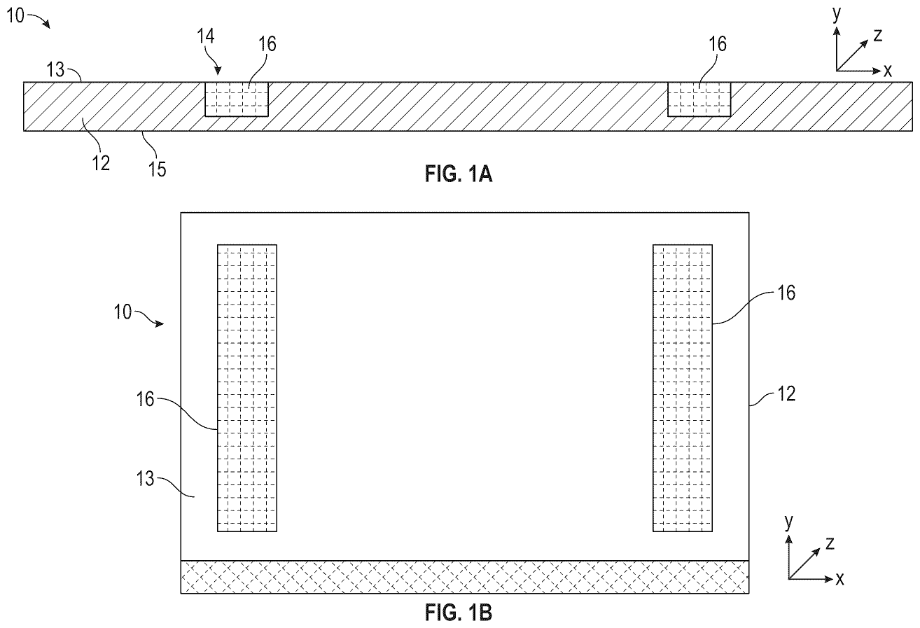

FIGS. 1A-1B are cross-sectional and perspective schematic representations, respectively, which are not to scale, of a workpiece 10 utilized in a process for making a semiconductor device such as, for example, a vertical NAND memory cell. The workpiece 10 includes a substrate 12 including a first major surface 13 and a second major surface 15. The first major surface 13 includes an arrangement 14 of electrical interconnects 16. In the example of FIGS. 1A-1B, the electrical interconnects 16 are linear source lines extending along the z-direction, but any type of electrical interconnects can be used as necessary for a particular application. The substrate 12 may include multiple portions that support and/or isolate one or more other conductive materials and insulative materials for routing electrical signals such as, for example, circuitry (e.g., control units) and/or interconnections provided for routing the signals.

The interconnects 16 may be made from any conductive material, and tungsten (W) or W silicide have been found to be suitable for a source line used to charge the souce of a memory device. In some examples, the substrate 12 is an insulator including, but not limited to, and oxide material such as SiOₓ. The first major surface 13 of the substrate 12 can optionally be planarized using a process such as chemical mechanical polishing (CMP).

In some examples (not shown in FIG. 1A), the workpiece 10 can optionally include additional substrate layers on the second major surface 15, each of which may include arrangements of electrical interconnects.

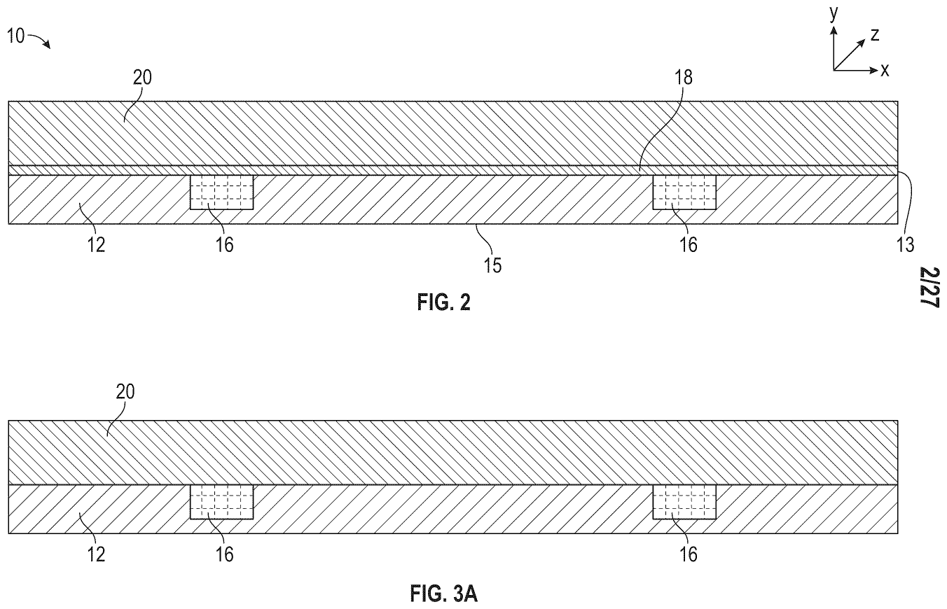

Referring now to FIG. 2, the workpiece 10 incudes a sacrificial layer 20 overlying the first major surface 13. In some examples, the sacrificial layer 20 may be made from an oxide material such as AlOₓ, or a metal such as W. In some examples, prior to application of the sacrificial layer 20, an optional oxide layer 18 may be applied over the surface 13 of the substrate 12.

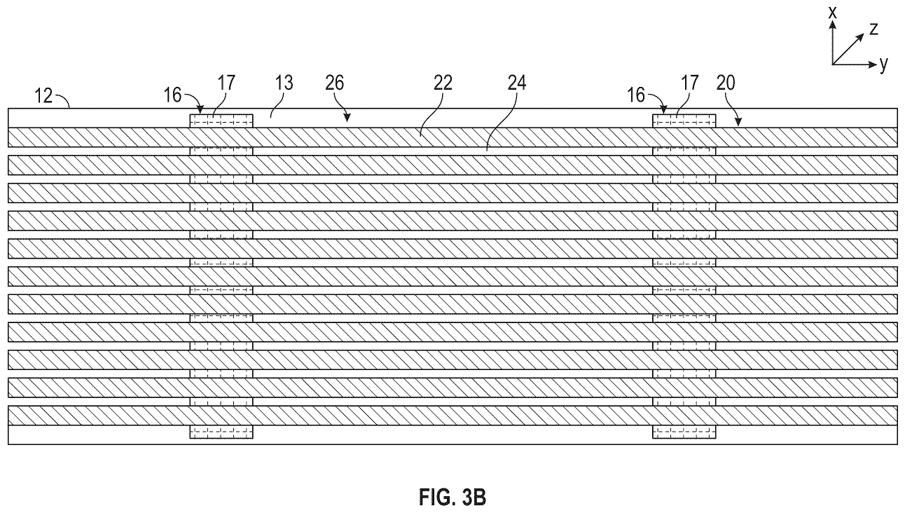

As shown in FIGS. 3A-3B, the sacrificial layer 20 may be patterned using, for example, a dry or wet etching step, to form an array 26 of substantially parallel linear ribs 22 separated by open channels 24. The array 26 may be regular or irregular, and can cover all or a portion of the surface 13 of the substrate 12. As illustrated in FIG. 3B, the ribs 22 and the corresponding channels 24 therebetween extend along the x-direction, and as such are arranged in a direction substantially normal to the direction of the source lines 16. The etch step forming the ribs 22 removes a sufficient amout of the sacrificial layer 20 to expose the surface 13 of the substrate 12, and to expose the surfaces 17 of the source lines 16.

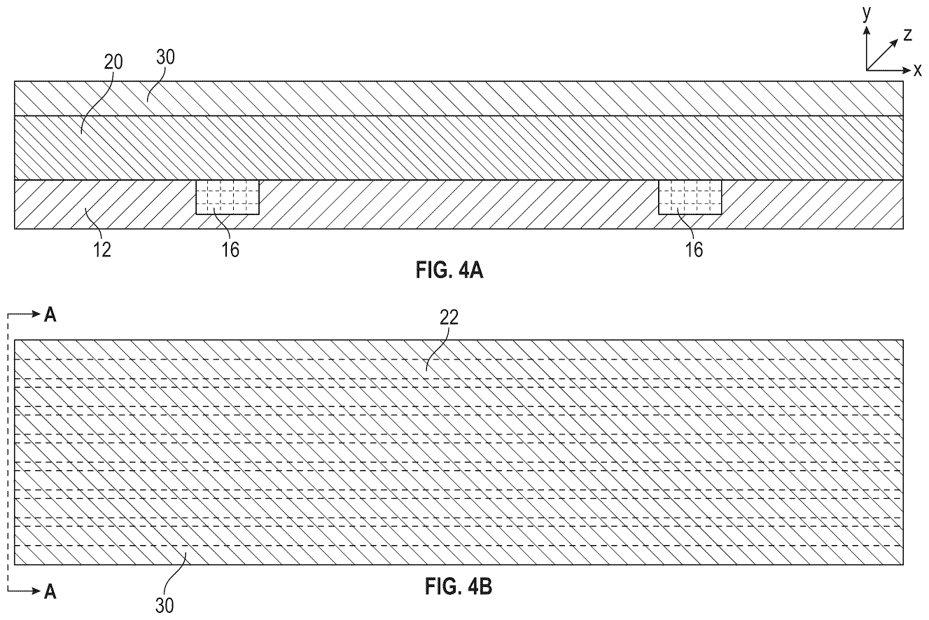

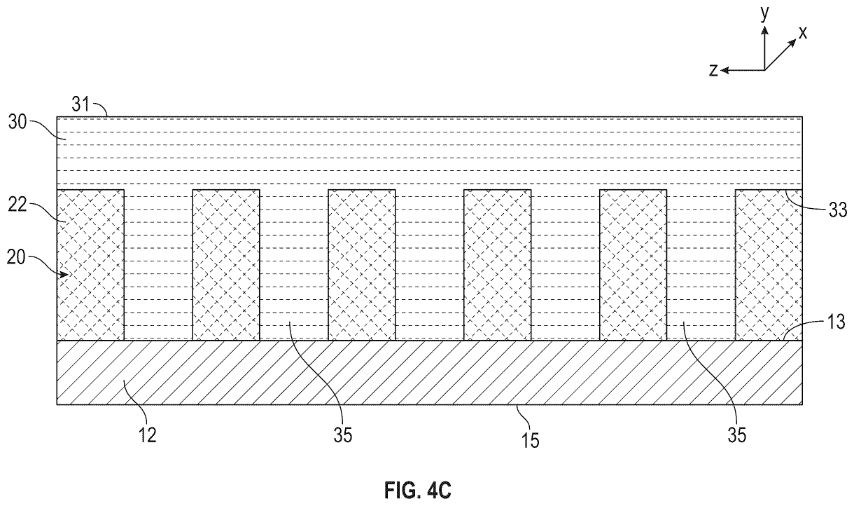

Referring now to FIGS. 4A-4C, a structural layer 30 may be deposited over the ribs 22 to substantially fill the channels 24. In some examples, the structural layer 30 may be formed from an oxide such as SiO₂, a nitride, or a series of layers of different materials depending on the structural strength and etch selectivity needed in subsequent process steps. As shown in FIG. 4C, which is a section taken along the line A-A in FIG. 4B, the structural layer 30 includes a substantially planar first major surface 31 and a second major surface 33. The second major surface 33 of the structural layer 30 includes an arrangement of flutes 35 that are formed in the channels 24 (FIG. 3B) of the sacrificial layer 20. The flutes 35 may have a wide variety of cross-sectional shapes as viewed along the x-direction, and the square or rectangular shape shown in FIG. 4C is only provided as an example. Other suitable cross-sectional shapes for the flutes 35 include trapezoidal, hemispherical, triangular, and the like.

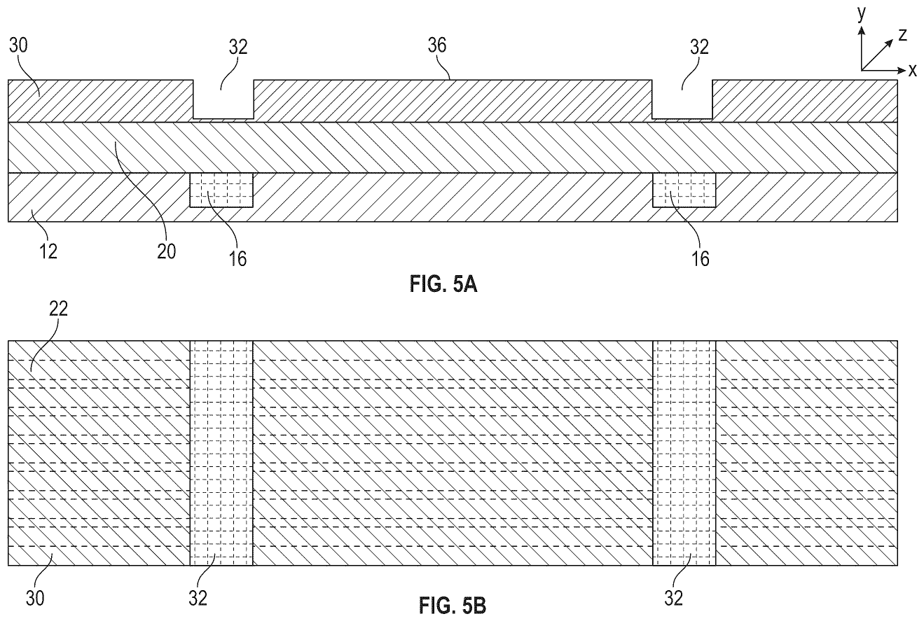

As shown in FIGS. 5A-5B, the structural layer 30 may be etched to form channels 32 that extend along the z-direction, substantially overlie the source lines 16, and extend in a direction normal to the direction of the ribs 22 in the sacrificial layer 20. After forming the channels 32, a liner 36 may optionally be applied over the structural layer 30. In some examples, the liner 36, which may be a single layer or multiple layers, may be formed from an oxide, a nitride, or a combination thereof.

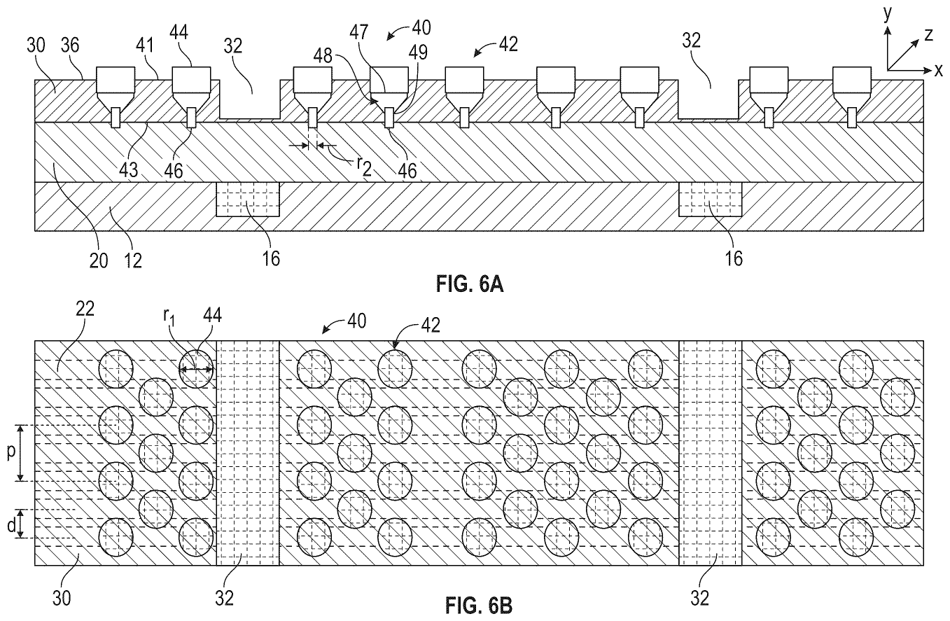

Referring now to FIGS. 6A-6B, an array 40 of vias 42 are etched into the structural layer 30. The number of vias 42 in the array 40, as well as the spacing of the vias 42, may vary depending on the intended application of the semiconductor device derived from the workpiece 10. However, as shown schematically in FIG. 6B, the vias 42 are formed to overlie the ribs 22 in the sacrificial layer 20. As shown in the example of FIG. 6B, when viewed along the z-direction, the vias 42 are arranged in staggered rows with a pitch P=2d, with d being the distance between adjacent ribs 22. Other arrangements can similarly be used.

In the example of FIGS. 6A-6B, the vias 42 extend along the y-direction, and as such extend in a direction normal to both the ribs 24 and the source lines 16. The vias 42 have an inlet region 44 proximal a first major surface 41 of the structural layer 30, and an outlet region 46 proximal an opposed second major surface 43 of the structural layer 30. In some examples, which are not intended to be limiting, the inlet region 44 and the oulet region 46 have a generally circular or oval cross-sectional shape. In the example of FIGS. 6A-6B, the diameter r₁ of the inlet region 44 of each via 42 is larger than the diameter r₂ of the outlet region 46, and the vias 42 include a funnel-shaped conical region 48 between the inlet region 44 and the outlet region 46.

The conical region 48 includes a base 47 proximal the first major surface 41 of the structural region 30, and an apex 49 proximal the second major surface 43 thereof. The apex 49 of the conical region 48 discharges into the outlet region 46. The funnel-shaped conical region 48 in the vias 42 may be formed in single or multiple etching steps, and in some examples a spacer may optionally be used to form the funnel shape.

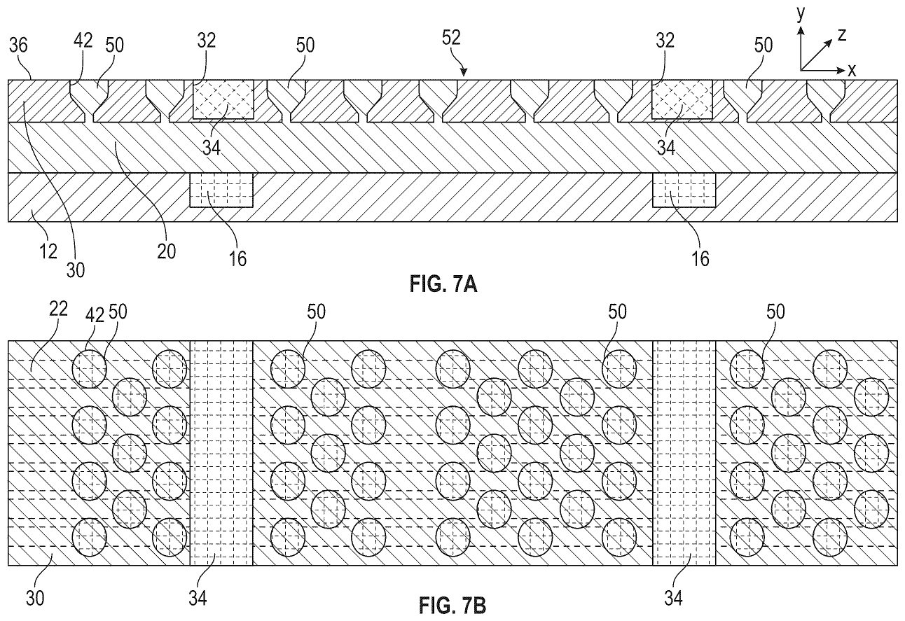

Referring now to FIGS. 7A-7B, the channels 32 are filled with an etch stop material to form an etch stop layer 34. As shown in FIGS. 7A-7B, the etch stop layer extends along the z-direction and overlies the source lines 16 in the substrate 12. The vias 42 are also filled with an etch-stop material to form etch-stop plugs 50. The etch stop plugs 50 extend to and are contiguous with the sacrifical layer 20 that underlies the structural layer 30. Suitable etch stop materials include, but are not limited to, W, AlOₓ, and the like. A planarizing process such as CMP may optionally be used to remove the etch stop material in the layers 34 and plugs 50 to form a substantially planar surface 52.

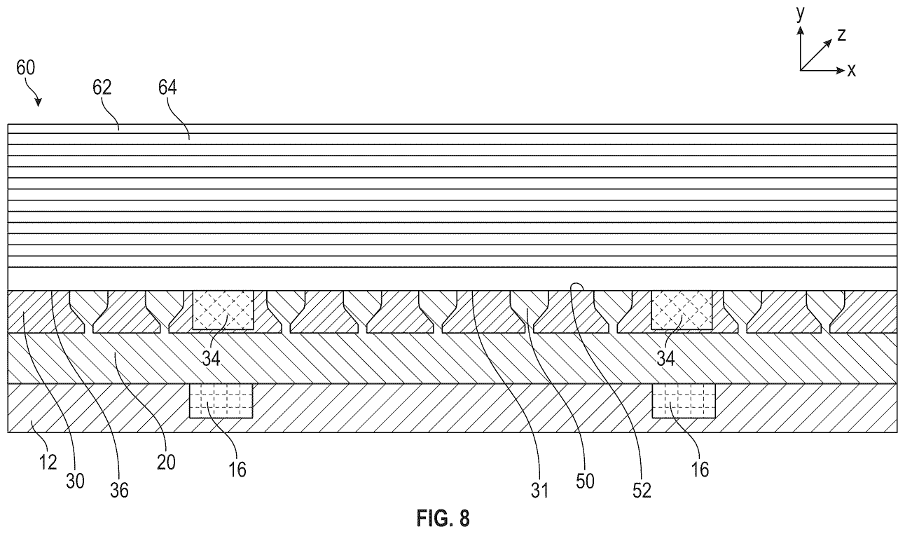

Referring now to FIG. 8, a tier deck 60 is applied on the surface 52, which forms a support for the tier deck 60. As shown schematically in FIG. 8, the tier deck 60 includes a stack formed from a plurality of pairs of alternating layers of dielectric materials 62 and nitride materials 64. The alternating pairs of layers 62, 64 are arranged in planes substantially parallel to a plane of the first major surface 31 of the underlying supporting structural layer 30. The tier deck 60 can include any suitable number of layers 62, 64 which have a thickness on the order of about 10 nm to about 100 nm, and the depiction in FIG. 8 is only provided as an example. The layer stack 60 and layers 62, 64 may be formed using conventional techniques.

The dielectric layers 62 are formed from a dielectric material including, but not limited to, a silicon oxide (SiOₓ), such as silicon dioxide (SiO₂), phosphosilicate glass, borosilicate glass, borophosphosilicate glass, fluorosilicate glass, titanium dioxide, zirconium dioxide, hafnium dioxide, tantalum oxide, magnesium oxide, aluminum oxide, or a combination thereof. The material in the layers 64 is a nitride material including, but not limited to, a silicon nitride (SiN). In some examples, the dielectric material in the layers 62 is SiO₂, and the nitride material in the layers 64 is SiN.

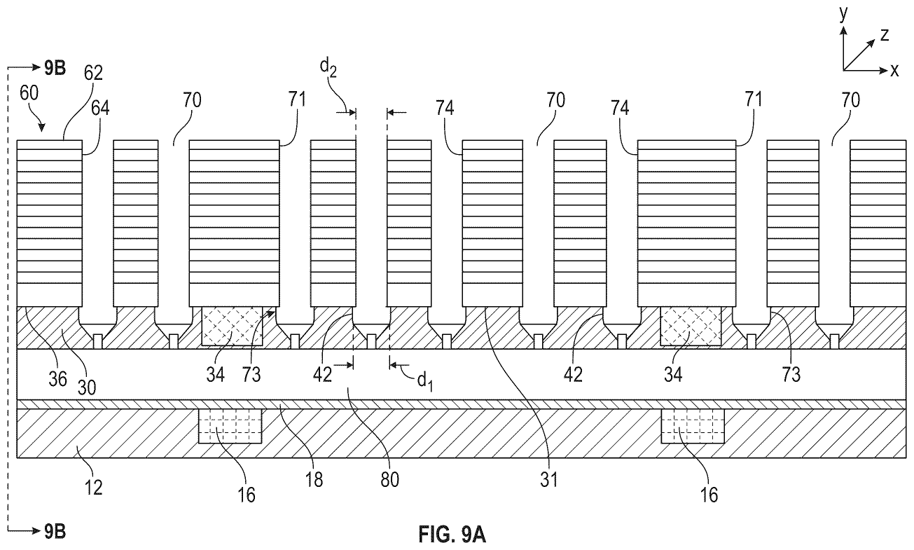

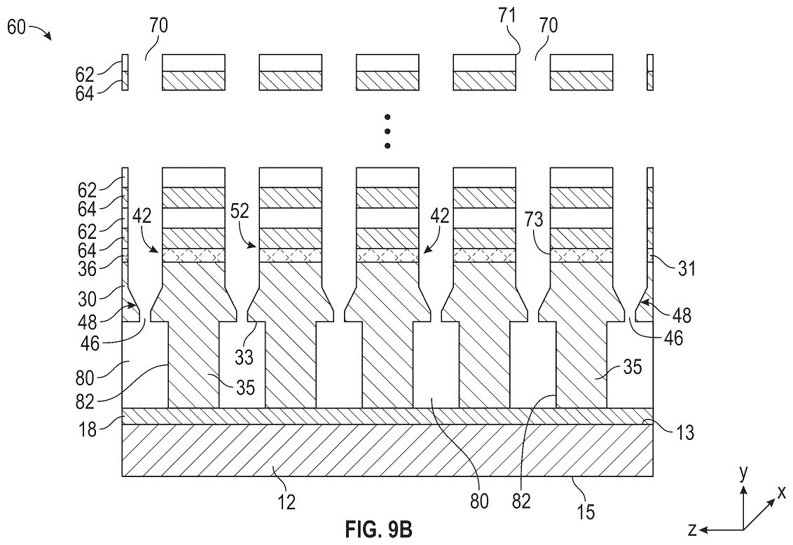

Referring now to FIG. 9A, an etch step can be utilized to form openings 70 in the tier stack 60 which, in subsequent process steps, can be filled with a conductive material to form, for example, a memory cell pillar. The etch step further removes the etch stop plugs 50 (FIG. 8) from the vias 42 in the structural layer 30, as well as all or a portion of the sacrificial layer 20 underlying the structural layer 30. The removal of the sacrificial layer 20 forms tunnel-like cavities 80 extending along the x-direction and positioned between the structural layer 30 and the substrate 12 (see also FIG. 9B discussed below).

The openings 70 are formed in the tier stack 60 to include a first end 71 and a second end 73 terminating a via 42 in the structural layer 30. As shown in FIG. 9A, the openings 70 extend in a direction substantially normal to a plane of the alternating layers of dielectric materials and nitride materials 62, 64 in the tier stack 60, and normal to a plane of the first major surface 31 of structural layer 30. In some examples, not shown in FIG. 9A, the openings 70 can have a substantially trapezoidal cross-sectional shape that tapers from a first diameter d₁ at the second end 73 to a second diameter d₂ at the first end 71, wherein d₂ is greater than d₁. The openings 70 include sidewalls 74 that bound the stacked pairs of layers of dielectric materials and nitride materials 62, 64.

Referring also now to FIG. 9B, which is not to scale, the openings 70 terminate in the vias 42 extending along the y-direction through the structural layer 30. The openings 70 are thus arranged between the flutes 35 in the structural layer 30. The structural layer 30 is corrugated, with the flutes 35 extending between the second major surface 33 thereof and the first major surface 13 of the substrate 12 (or on the optional oxide layer 18 on the surface 13). The flutes 35 in the structural layer 30 provide structural support to the tier stack 60, and such structural support can maintain the dimensions of the openings 70 during subsequent process steps.

The conical regions 48 of the vias 42 terminate in the outlet regions 46, which discharge into the cavities 80 between the flutes 35. As shown in FIG. 9B, the cavities 80 thus provide access to the openings 70. The cavities 80 include exposed walls 82.

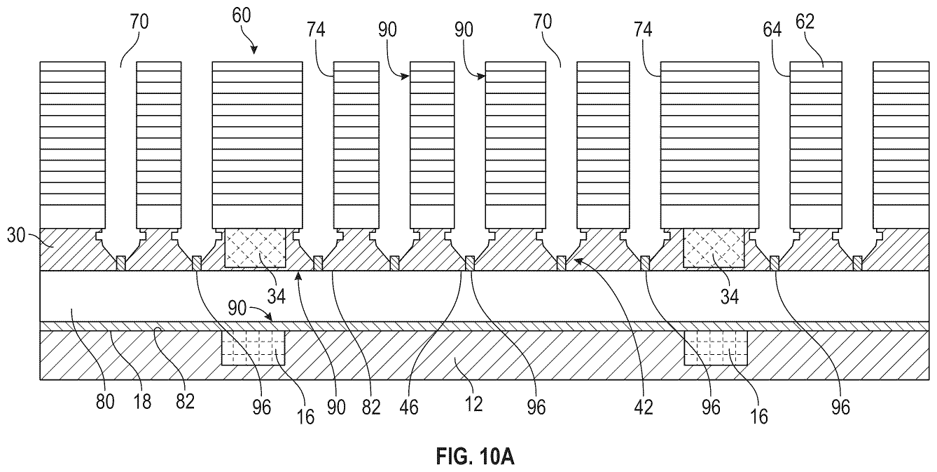

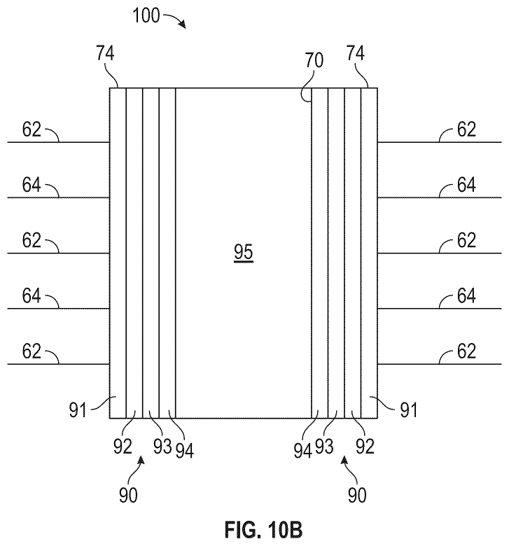

Referring now to FIGS. 10A-10B, an arrangement of channel poly layers 90 is deposited on the sidewalls 74 of the openings 70, and futher overlies the exposed walls 82 within the cavities 80. The channel poly layers 90 are deposited in the openings 70 in an amount sufficient to form plugs 96 in the outlet regions 46 of the vias 42.

As shown schematically in the example of FIG. 10B, the channel poly layers 90 include a blocking oxide layer 91 of, for example, SiO₂, contacting the sidewalls 74, 82. A storage nitride layer 92 of, for example, silicon nitride, is applied on the blocking oxide layer 91. A tunnel oxynitride layer 93 of, for example, silicon oxynitride, is deposited over the storage nitride layer 92. A transistor channel poly layer 94 of, for example, polysilicon, is applied over the tunnel oxynitride layer 93. The channel poly layer 90 may optionally be oxidized as necessary to reduce to a desired thickness of about 4 nm to about 15 nm, or about 5 nm to about 10 nm, for enhanced control of subsequent etch steps. In some examples, any of the channel poly layers 90 may optionally be lightly doped, or in-situ doped during deposition, as needed, to alter layer conductivity under biasing conditions.

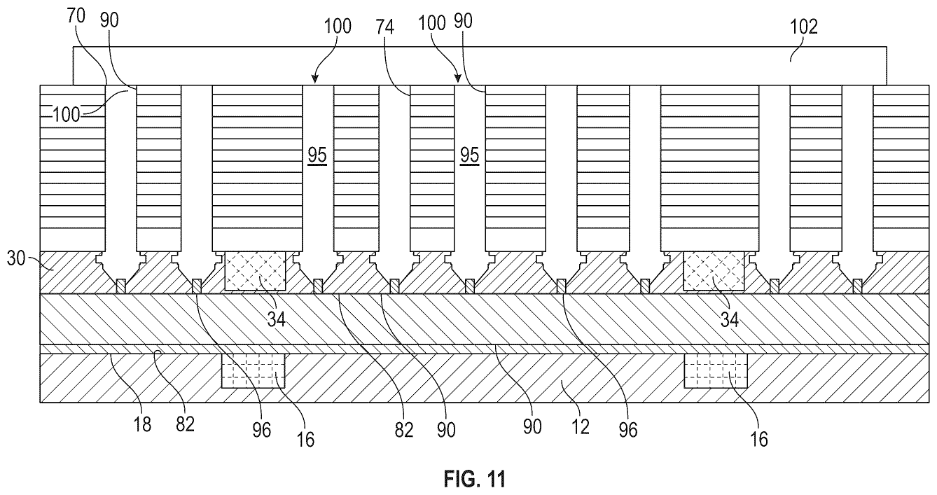

Referring also to FIG. 11, columns 95 of, for example, SiO₂, are deposited between the opposed channel poly layers 90 forms conductive pillars 100 that extend along the y-direction and form the source/drain gates for the integrated circuit device (see also FIG. 11). The SiO₂ columns 95 completely fills the openings 70 between the channel poly layers 90, and may be substantially free of voids (e.g., air gaps). The materials used to form the channel poly layers 90 and the columns 95 formed in the opening 70 and over the tiers 60 may be removed, such as by CMP. An optional protective cover 102 may be applied to protect the pillars 100 during subsequent process steps.

A drain of N⁺ poly (not shown in FIG. 11) may be formed at the tops of the pillars 100, but only at the top above the SGD transistors. A drain contact may be formed above the SGD transitors at the top of the pillars 100, and may be formed from conductive materials including, but not limited to, a tungsten-containing material, a titanium-containing material, or a combination thereof.

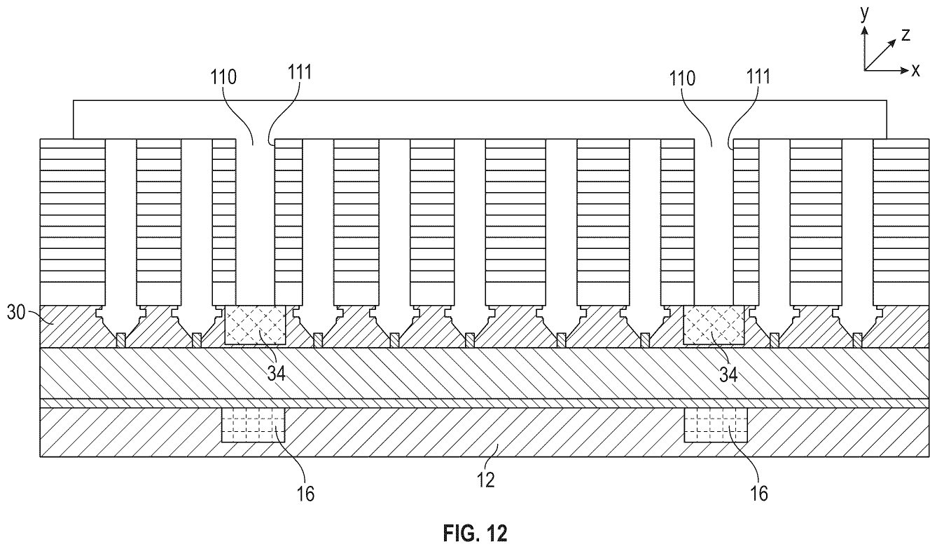

Referring now to FIG. 12, the tiers 60 are etched to form substantially linear slits 110 extending along the z-direction. The slits 110, which include walls 111, extend into the etch stop layer 34 and are substantially aligned with the source lines 16. The slits 110 may be formed using a single or multiple etch steps.

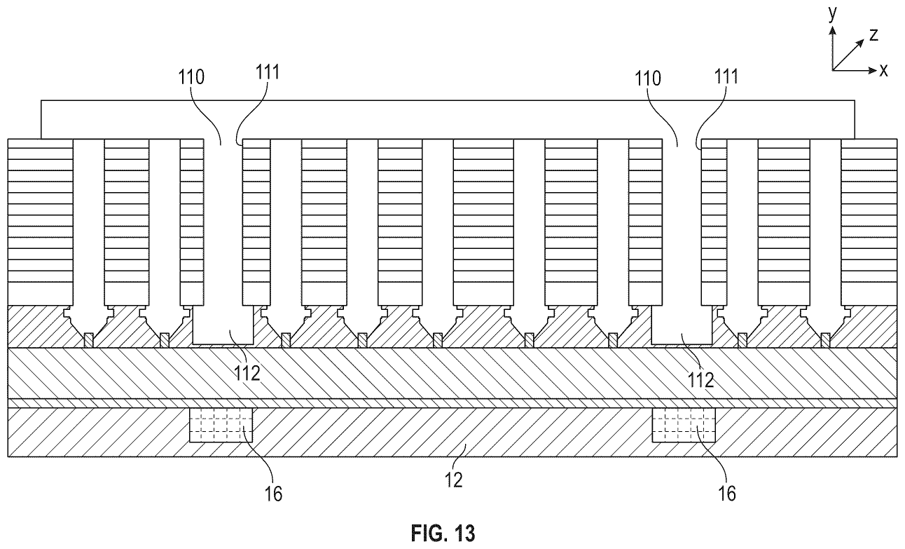

In FIG. 13, the etch stop layers 34 (FIG. 12) are exhumed via the slits 110, which forms an arrangement of voids 112 extending along the z-direction and aligned with the source lines 16.

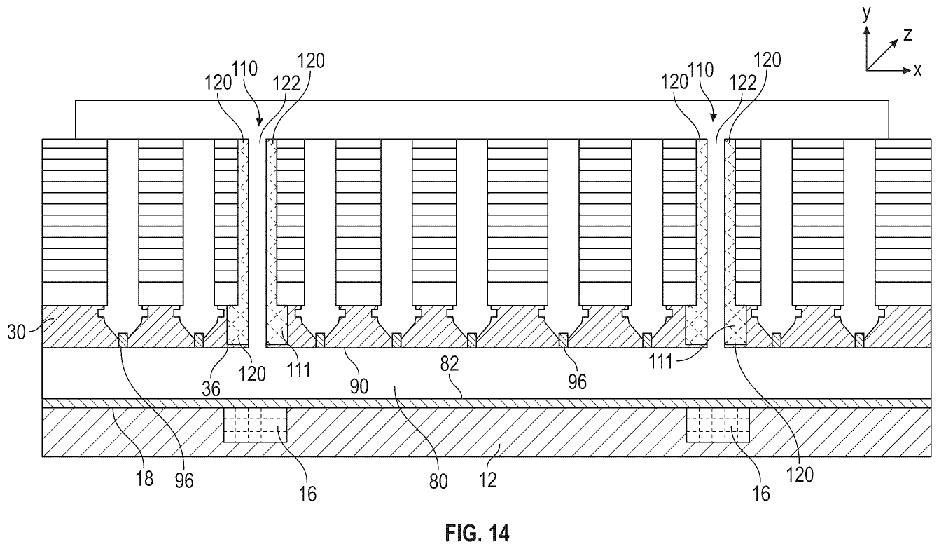

As shown in FIG. 14, a nitride spacer layer 120 is applied along the walls of the slits 110 which further occupies the voids 112 (FIG. 13). An etch step is then used to form an opening 122 within the nitride spacer layer 120. The opening 122 extends along the y-direction through the liner 36, the channel poly layer 90 along the walls 82, and discharges into the cavities 80.

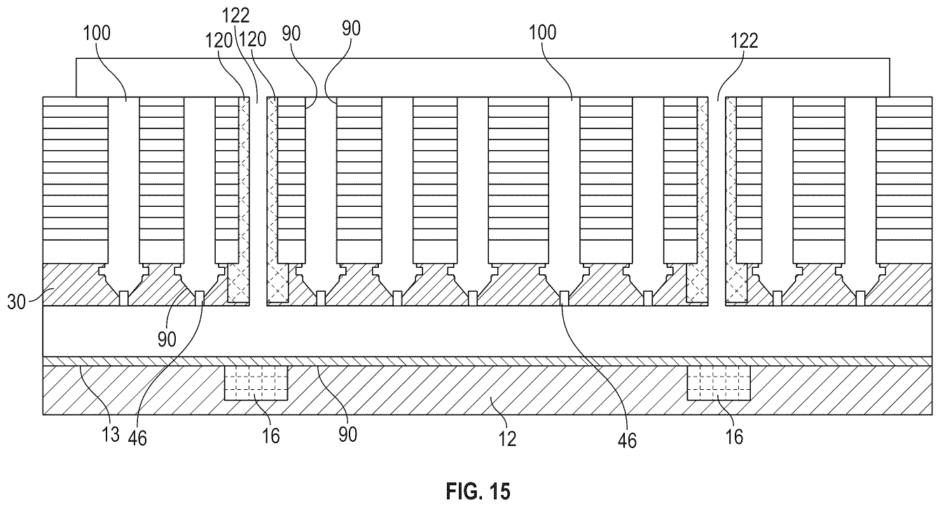

Referring now to FIG. 15, the channel poly layer 90 is selectively etched from the walls 82 of the cavity 80. The channel poly layer 90 is further etched to remove the plugs 96 from the outlet regions 46 of the vias 42. Thus, the open outlet regions provide access to the channel poly layer 90 along the walls 74 of the openings 70, as well as the pillars 100. This selective etch step further allows selective etching of the channel poly layer 90 in the cavities and the outlet region 46 without impacting the channel poly layers 90 adjacent to the pillars 100.

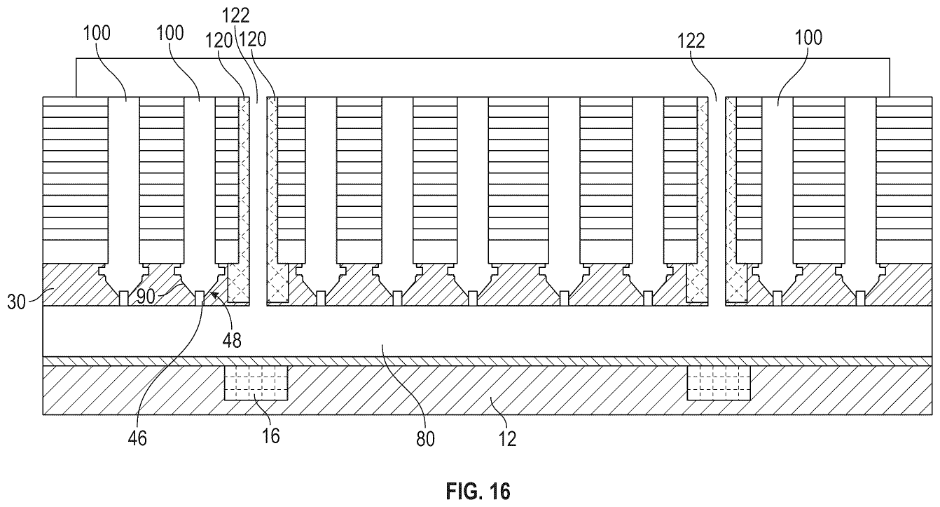

In FIG. 16, an etchant is applied to optionally further etch back the SiO₂ oxide fill making up the pillars 100 and remove the SiO₂ oxide fill from the funnel-shaped conical regions 48 of the vias 42. The channel poly layers 90 (FIG. 10B) in the conical regions 48 of the vias 42 can be used to limit the extent of the etching. Following the etch-back step, a phosphorous-rich oxide may be applied to dope the channel poly layers 90 (FIG. 10B) within the conical region 48. The doping forms an n-type polysilicon layers in the channel poly layers 90 within the conical region 49, which allows for a subsequent ohmic contract to the channel poly layers 90. Following the doping step, the P-rich oxide may be removed from exposed surfaces of the channel poly layers 90.

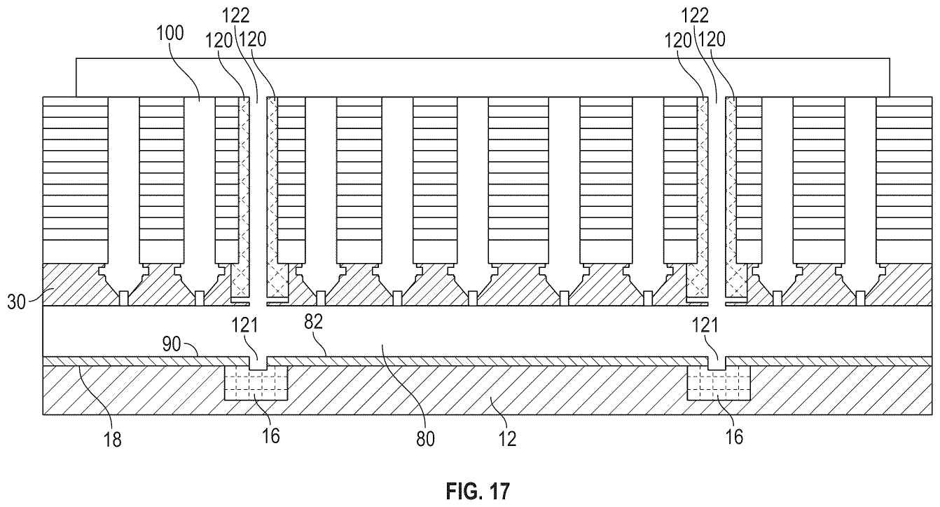

Referring now to FIG. 17, the openings 122 in the slits 110 are further etched to punch through the channel poly layers 90 on the walls 82 of the cavities 80 and through any oxide layer 18 present on the substrate. The etch opens access passages 121 to the source lines 16 in the substrate 12 via the slits 110.

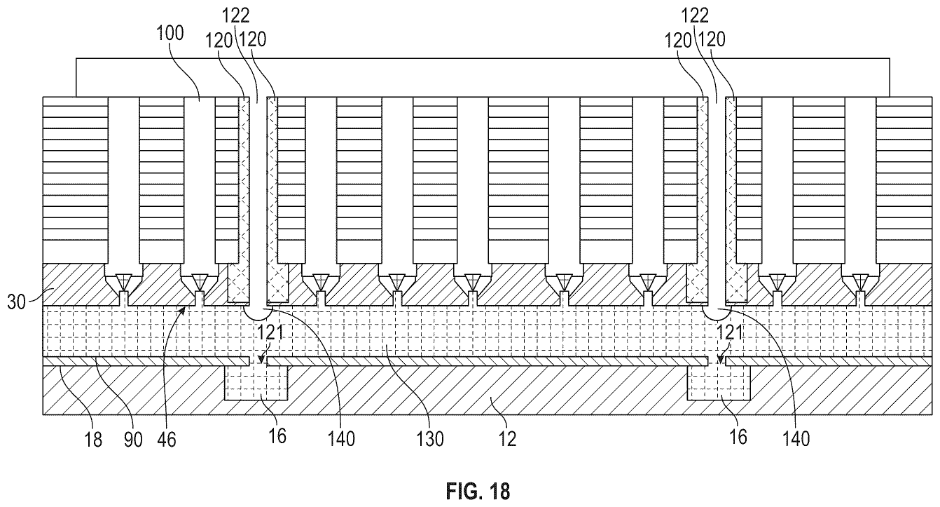

As shown in FIG. 18, a conductive metal or metal alloy 130 such as, for example, Ti, TiN, W, and mixtures and combinations thereof, is deposited within the cavities 80 such that the metal or metal alloy enters the outlet regions 46 of the vias 42, as well as the access regions 121 overlying the source lines 16. The metal or metal alloy may then be annealed and heated to form a Ti silicide on the exposed n-type polysilicon layers 92 of the channel poly layers 90, thus creating an ohmic contact between the metal or metal alloy 130 and the channel poly layers 90 within the conical region 48 at the bottom of the pillar 100. In some examples, the TiN keeps W from lifting and W forms the main conductor within the cavities 80.

Following deposition of the metal or metal alloy, a wet etch step may be performed to remove W from the openings 122 in the slits 110, to form mushroom-shaped cavities 140.

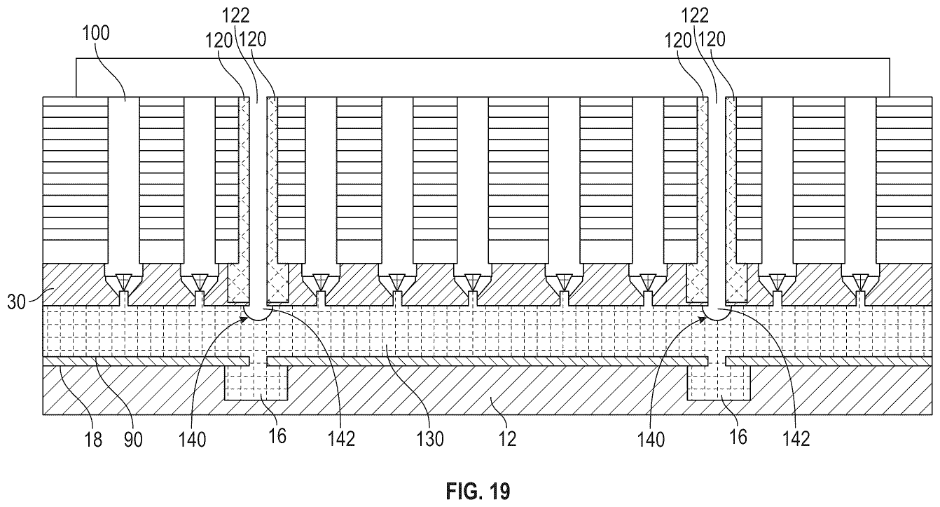

As shown in FIG. 19, the mushroom-shaped cavities 140 may be filled with an oxide to prevent etchant during subsequent nitride word line exhume and replacement steps. The oxide may then be etched back to form a plug 142 in the mushroom-shaped cavities 140.

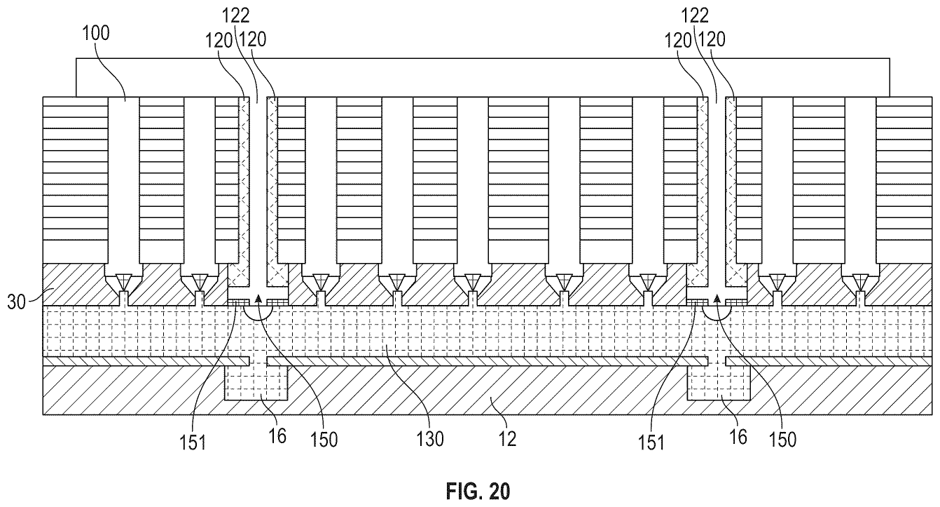

Referring to FIG. 20, an optional etch step may be used to selectively remove any conductive metals such as W from the regions 150 within the openings 122 in the slits 110. An oxide layer 151 such as, for example, SiO₂, remains on the metal or metal alloy layer 130 to protect the layer 130 during later nitride exhumation steps.

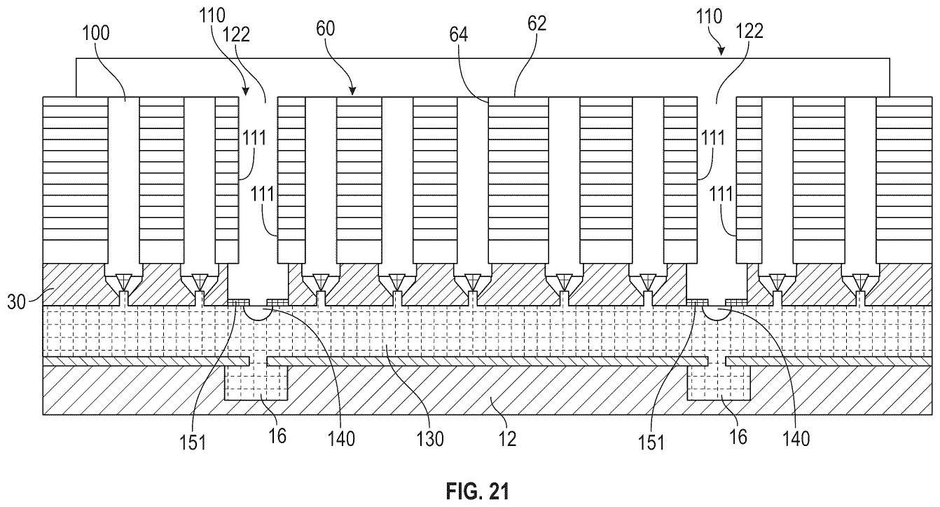

In FIG. 21, the nitride layers 120 (FIG. 20) are removed from the walls 111 of the slits 110, leaving intact the oxide layers 151. During the nitride removal step, the nitride layers 64 are also removed from the tiers 60 where word lines will subsequently be formed. The layers 120 and 64 of the nitride materials may be removed, such as by a wet etch process (e.g., an isotropic etch process), that utilizes an etch chemistry selective for the nitride materials relative to the dielectric materials 62 in the tier stack 60.

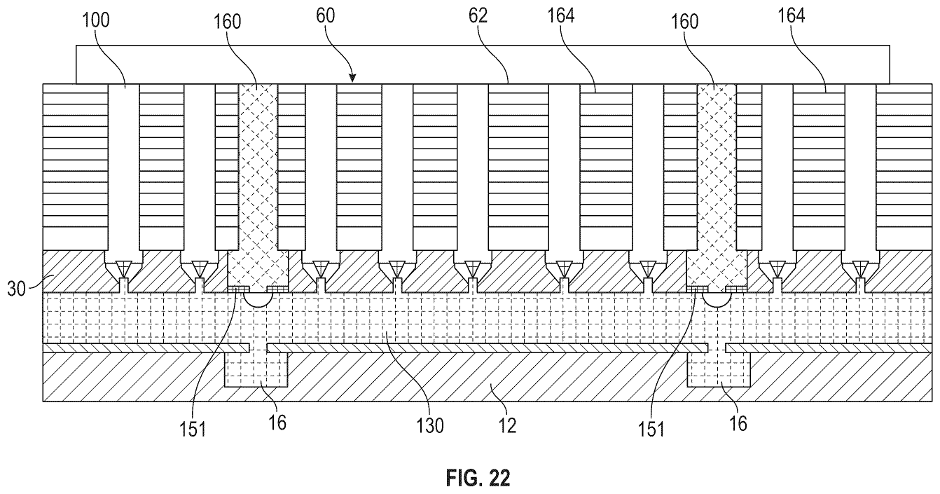

Referring now to FIG. 22, following the nitride removal step of FIG. 20, a dielectric material 164 such as, for example, SiO₂, is deposited, followed by deposition of a conductor or a dielectric material (not shown in FIG. 22). The dielectric materials 164 are formed in the spaces previously occupied by the nitride layers 64. The dielectric materials 164 that replace the nitride materials in the layers 64 correspond to word lines (e.g., access lines) of the memory cells and other of the conductive materials in the tiers 60 correspond to select gate sources/select gate drains of the memory cells. In some examples, which are not intended to be limiting, the dielectric and conductive materials that may be deposited to replace the nitrides in the layers 164 include a metal (e.g., tungsten, titanium, molybdenum, niobium, vanadium, hafnium, tantalum, chromium, zirconium, iron, ruthenium, osmium, cobalt, rhodium, iridium, nickel, palladium, platinum, copper, silver, gold, aluminum), a metal alloy (e.g., a cobalt-based alloy, an iron-based alloy, a nickel-based alloy, an iron- and nickel-based alloy, a cobalt- and nickel-based alloy, an iron- and cobalt-based alloy, a cobalt- and nickel- and iron-based alloy, an aluminum-based alloy, a copper-based alloy, a magnesium-based alloy, a titanium-based alloy, a steel, a low-carbon steel, a stainless steel), a conductive metal-containing material (e.g., a conductive metal nitride, a conductive metal silicide, a conductive metal carbide, a conductive metal oxide), a conductively-doped semiconductor material (e.g., conductively-doped silicon, conductively-doped germanium, conductively-doped silicon germanium), or a combination thereof. The conductive materials may be deposited to replace the nitride layers 64 by conventional techniques. In some embodiments, the conductive materials residing the layers previously occupied by the nitrides are polysilicon.

As shown in FIG. 22, following the formation of the word lines, the slits 110 are filled with an appropriate material 160 including, for example, oxides, poly, and conductors, and combinations thereof, and then planarized.

Various deposition techniques for components of structures in the process flow above can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum are methods, among others. CVD can include, but is not limited to, plasma chemical vapor deposition and laser chemical vapor deposition, among others. Selective etching and conventional masking techniques can be used to remove selected regions in the processing discussed above. Etching procedures can include, but are not limited to, wet etching, dry etching, and atomic layer etching deposition, among others.

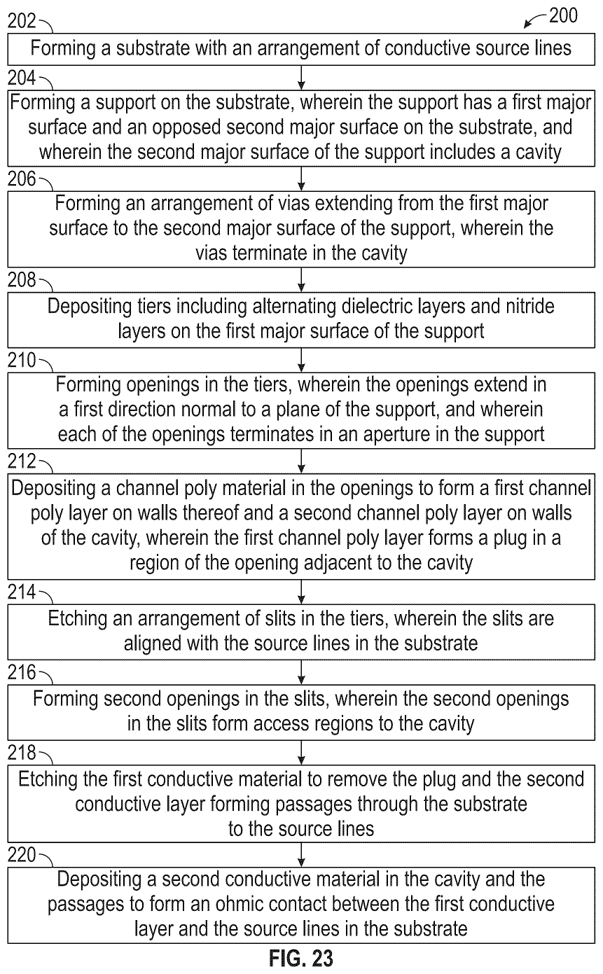

FIG. 23 is a flow diagram of features of an embodiment of an example method 200 for making a semiconductor device, or a workpiece processable to form a semiconductor device.

Step 202 of the method 200 includes forming a substrate with an arrangement of conductive source lines.

Step 204 of the method 200 includes forming a support on the substrate, wherein the support has a first major surface and an opposed second major surface on the substrate, and wherein the second major surface of the support includes a cavity.

Step 206 of the method 200 includes forming an arrangement of vias extending from the first major surface to the second major surface of the support, wherein the vias terminate in the cavity.

Step 208 of the method 200 includes depositing tiers including alternating dielectric layers and nitride layers on the first major surface of the support.

Step 210 of the method 200 includes forming openings in the tiers, wherein the openings extend in a first direction normal to a plane of the support, and wherein each of the openings terminates in an aperture in the support.

Step 212 of the method 200 includes depositing a channel poly material in the openings to form a first channel poly layer on walls thereof and a second channel poly layer on walls of the cavity, wherein the first channel poly layer forms a plug in a region of the opening adjacent to the cavity.

Step 214 of the method 200 includes etching an arrangement of slits in the tiers, wherein the slits are aligned with the source lines in the substrate.

Step 216 of the method 200 includes forming second openings in the slits, wherein the second openings in the slits form access regions to the cavity.

Step 218 of the method 200 includes etching the first channel poly layer to remove the plug and the second conductive layer;

Step 220 of the method 200 includes forming passages through the substrate to the source lines.

Step 222 of the method 200 includes depositing a conductive material in the cavity and the passages to form an ohmic contact between the first conductive layer and the source lines in the substrate.

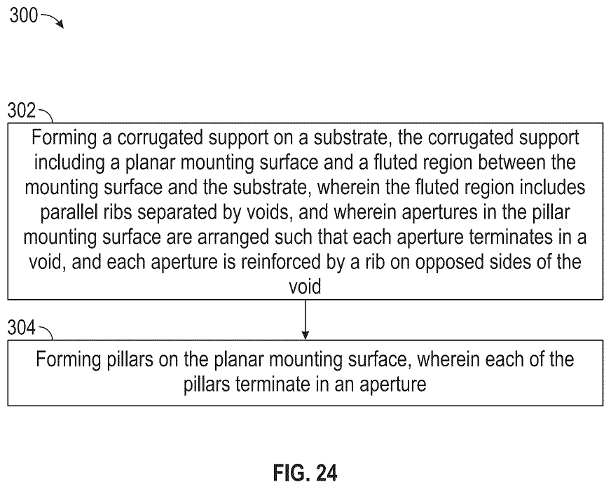

FIG. 24 is a flow diagram of features of an embodiment of another example method 300 of forming a semiconductor device or a workpiece processable to form a semiconductor device.

At step 302, the method 300 includes forming a corrugated support on a substrate, the corrugated support including a planar mounting surface and a fluted region between the mounting surface and the substrate, wherein the fluted region includes parallel ribs separated by voids, and wherein apertures in the pillar mounting surface are arranged such that each aperture terminates in a void, and each aperture is reinforced by a rib on opposed sides of the void.

At step 304, the method 300 includes forming pillars on the planar mounting surface, wherein each of the pillars terminate in an aperture.

In some examples, as described in detail above, a memory array of a 3D memory device can extend in a horizontal plane along a substrate, which can be designated as a x-y plane, and in a vertical direction, taken as the z direction perpendicular to the x-y plane. Design considerations can be implemented with the 3D memory arrays such as using a circuit-under-array (CuA) architecture to enhance reduction of die size or increase utilization of space in a die. CuA refers generally to circuitry located in a memory die under a memory array of the memory die. The CuA can include control logic and sensing circuitry for sensing the programmed data states of memory cells of the memory array. With the control logic and sensing circuitry fabricated below the memory array, using semiconductor processing that can include CMOS processing technology, CuA can be referred to as CMOS under array.

For a 3D NAND memory array, which can include vertical strings of the memory cells of the present disclosure, using floating gate transistors or charge trap transistors, and connections from data lines positioned above the 3D NAND, vertical connections extending through the 3D NAND memory array or through memory breaks within the 3D NAND memory array can be used to couple to sensing circuitry and other control logic of the CuA for the memory array. A CuA architecture, which allows for circuits that operate with a 3D memory array to be structured in a space in the substrate below the 3D memory array, provides capabilities for higher densities of memory cells. These capabilities address a desire to limit increases in the area (horizontal plane) of the memory die. For continued increases in memory capacity, other design considerations can be implemented that also provide for enhancements to reduction of parasitic structures in operation of the memory device.

Various memory device formats can be structured in a CuA architecture, such as but not limited to NOR or NAND architecture semiconductor memory arrays. Both NOR and NAND flash architecture semiconductor memory arrays are accessed through decoders that activate specific memory cells by selecting the access line coupled to their gates. In a NOR architecture semiconductor memory array, once activated, the selected memory cells place their data values on data lines, causing different currents to flow depending on the state at which a particular cell is programmed. In a NAND architecture semiconductor memory array, a relatively high bias voltage is applied to a drain-side select gate (SGD) line. Access lines coupled to the gates of the unselected memory cells of each group are driven at a specified pass voltage (e.g., Vpass) to operate the unselected memory cells of each group as pass transistors (e.g., to pass current in a manner unrestricted by their stored data values). Current then flows between the source line and the data line through each series-coupled group, restricted only by the selected memory cells of each group, placing current encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC can refer to a memory cell that can store two bits of data per cell (e.g., one of four programmed states), a triple-level cell (TLC) can refer to a memory cell that can store three bits of data per cell (e.g., one of eight programmed states), and a quad-level cell (QLC) can store four bits of data per cell. MLC is used herein in its broader context to refer to any memory cell(s) that can store more than one bit of data per cell (i.e., that can represent more than two programmed states). The sensing and control circuitry for such NOR or NAND architecture semiconductor memory arrays can be structured beneath the respective memory array in a CuA architecture.

In a CuA architecture for a memory die having a 3D memory array, the CuA region can include circuits for controlling the operation of the 3D memory array. One or more control circuits of the CuA can provide control signals to the 3D memory array in order to perform a read operation or a write operation on the 3D memory array. The CuA can include one or more of control circuitry, state machines, decoders, sense amplifiers, read/write circuits, and controllers. These circuits can implement one or more memory array operations including erasing, programming, or reading operations. For example, the CuA region can include an on-chip memory controller for determining row and column address, access line and data line addresses, memory array enable signals, and data latching signals. The operations on the 3D memory array are typically performed to access one or more memory cells in response to requests from other circuits on the memory die or a device external to the memory die. The CuA region can include pad structures to couple the memory array or one or more circuits in the CuA region to other portions of the die of the memory device, or to couple to devices external to the memory device.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

To better illustrate the methods, structures, and apparatuses described herein, a non-limiting set of Example embodiments are set forth below as Examples.

Example A includes a semiconductor device, comprising: a substrate comprising an arrangement of conductive interconnects; a corrugated support on the substrate, wherein the support comprises: a substantially planar first major surface and an opposed second major surface proximal to the substrate, the first major surface comprising a plurality of vias extending along a first direction, wherein the vias comprise an inlet at a first major surface of the support and an outlet at the second major surface of the support, and an arrangement of flutes on the second major surface of the support, wherein the flutes extend along a second direction normal to the first direction, wherein the flutes are separated by voids, and wherein the vias terminate in the voids.

In Example B, the subject matter of Example A includes vias that comprise a conical region having an apex connected to the outlet.

In Example C, the subject mattere of Examples A and B includes flutes that comprise parallel linear ribs with a height extending along the first direction and a length extending along the second direction.

In Example D, the subject matter of Example C includes voids with a trapezoidal cross-sectional shape when viewed along the second direction.

In Example E, the subject matter of Example D includes ribs that comprise a substantially planar plateau region proximal to the substrate.

In Example F, the subject matter of any of Examples A to E includes vias that comprise a channel poly material in ohmic contact with a conductive material in the voids.

In Example G, the subject matter of Example F includes conductive material that contacts the conductive interconnects in the substrate.

In Example H, the subject matter of any of Examples A to G includes tiers on the first major surface of the support, the tiers comprising a stack of alternating conductive layers and non-conductive layers arranged in planes substantially parallel to a plane of the first major surface of the support.

In Example I, the subject matter of Example H includes tiers that further comprise slits extending therethrough along a third direction normal to the first direction and the second direction.

In Example J, the subject matter of Example I includes slits that comprise a conductive material in ohmic contact with the conductive material in the voids.

In Example K, the subject matter of any of Examples A to J includes a corrugated support comprising an oxide material.

In Example L, the subject matter of any of Examples A to K includes an oxide layer between the corrugated support and the substrate.

Example M is directed to a semiconductor device, comprising: a support on a substrate, wherein the support comprises a substantially planar first surface and a second surface opposite the first surface, wherein the second surface comprises an array of flutes separated by voids, and wherein the flutes extend along a first direction; tiers on the first surface of the support, the tiers comprising a stack of alternating dielectric layers and nitride layers, wherein the dielectric layers and nitride layers are arranged in planes substantially parallel to a plane of the first surface of the support; and a plurality of openings extending through the tiers and terminating in apertures extending through the support, wherein the openings extend along a second direction normal to the first direction, and wherein the apertures are arranged such that each opening overlies a void between two adjacent flutes in the support.

In Example N, the subject matter of Example M further includes tiers comprising slits extending therethrough along a third direction normal to the first direction and the second direction.

In Example O, the subject matter of any of Examples M or N includes flutes that comprise parallel linear ribs having substantially planar top surfaces proximal to the substrate.

In Example P, the subject matter of Example O includes voids with a trapezoidal cross-sectional shape when viewed along the second direction.

In Example Q, the subject matter of any of Examples M to P includes apertures in the support comprising an inlet at the first major surface thereof and an outlet at the second major surface thereof, and a conical region between the inlet and the outlet.

In Example R, the subject matter of Example Q includes an apex of the conical region proximal to the voids.

Example S is directed to a workpiece processable to form a semiconductor device, the workpiece comprising: a substrate comprising an arrangement of interconnect structures; and a corrugated support on a major surface of the substrate, wherein the corrugated support comprises: a substantially planar first major surface in a plane substantially parallel to the substrate, a second major surface opposed to the first major surface, wherein the second major surface comprises substantially parallel linear ribs separated by channels, each of the ribs having a height extending in a first direction normal to a plane of the first major surface and a length extending in a second direction substantially normal to the first direction; and a plurality of vias extending in the first direction through the corrugated support from the first major surface to the second major surface thereof, wherein each of the vias comprises an inlet on the first major surface of the corrugated support and an outlet in a channel.

In Example T, the subject matter of Example S includes at least a portion of the vias comprising a conical region having a base proximal to the first major surface of the support and an apex proximal the second major surface thereof.

In Example U, the subject matter of Example T in which the vias comprise a substantially cylindrical outlet region between the apex of the conical region and the outlet.

In Example V, the subject matter of Example U includeus at least a portion of the vias comprising a channel poly material in the cylindrical outlet region and the conical region.

In Example W, the subject matter of any of Examples S to V includes at least a portion of the interconnect structures in the substrate that extend along a third direction substantially normal to the first direction and the second direction.

In Example X, the subject matter of any of Examples S to W includes, on at least a portion of the first major surface of the support, tiers of alternating dielectric layers and nitride layers, and wherein the dielectric layers and nitride layers reside in a plane parallel to the plane of the first major surface of the support.

In Example Y, the subject matter of Example X includes an arrangement of slits in the tiers, wherein the slits extend along a third direction normal to the first direction and the second direction.

In Example Z, the subject matter of Example X includes openings in the tiers, wherein the openings extend along the first direction and terminate in the vias in the support.

In Example AA, the subject matter of Example Z includes at least a portion of the openings comprising walls having thereon a channel poly layer.

In Example BB, the subject matter of Example AA includes channel poly layer comprising layers of oxide and nitride.

In Example CC, the subject matter of Example BB includes the channel poly layer that forms an occluding plug in the vias.

In Example DD, the subject matter of Examples BB or CC includes a channel poly layer that comprises a dopant.

Example EE is directed to a semiconductor device, comprising: an insulative substrate with a major surface; a corrugated oxide support on the major surface of the insulative substrate, wherein the support comprises a substantially planar first major surface and an opposed second major surface, the second major surface of the support comprising a plurality of parallel linear ribs with a height extending along a first direction normal to the support and a length extending along a second direction normal to the first direction, the linear ribs being separated by voids, tiers comprising a stack of alternating dielectric layers and nitride layers on the first major surface of the insulative substrate; and a plurality of openings extending along the first direction through the tiers and terminating in vias extending through the support, wherein the vias are arranged between the ribs of the structural layer and terminate in the voids, and wherein the openings comprise a first channel poly material in ohmic contact with a conductive material in the in the voids.

Example FF includes the subject matter of Example EE, further comprising an array of slits extending through the tiers and the structural layer, wherein the slits extend along a third direction normal to the first direction and the second direction, and wherein the slits comprise a conductive material in ohmic contact with the conductive material in the voids.

Example GG includes the subject matter of Examples EE or FF, wherein at least a portion of the openings comprise walls having thereon a channel poly layer.

Example HH includes the subject matter of Example GG, wherein the channel poly layers comprise layers of oxide and nitride.

Example II is directed to a method for making a semiconductor device, the method comprising: forming a substrate comprising an arrangement of conductive source lines; forming a support on the substrate, wherein the support has a first major surface and an opposed second major surface on the substrate, and wherein the second major surface of the support comprises a cavity; forming an arrangement of vias extending from the first major surface to the second major surface of the support, wherein the vias terminate in the cavity; depositing tiers comprising alternating dielectric layers and nitride layers on the first major surface of the support; forming openings in the tiers, wherein the openings extend in a first direction normal to a plane of the support, and wherein each of the openings terminates in an aperture in the support; depositing a channel poly material in the openings to form a first channel poly layer on walls thereof and a second channel poly layer on walls of the cavity, wherein the first channel poly layer forms a plug in a region of the opening adjacent to the cavity; etching an arrangement of slits in the tiers, wherein the slits are aligned with the source lines in the substrate; forming second openings in the slits, wherein the second openings in the slits form access regions to the cavity; etching to remove the first channel poly layer and the second channel poly layer; forming passages through the substrate to the source lines; and depositing a conductive material in the cavity and the passages to form an ohmic contact between the first channel poly layer and the source lines in the substrate.

Example JJ includes the subject matter of Example II, wherein the cavity comprises parallel linear channels separated by linear ribs, and wherein the ribs and channels extend in a second direction normal to the first direction.

Example KK includes the subject matter of Examples II or JJ, further comprising applying an oxide layer between the support and the substrate.

Example LL includes the subject matter of Examples II to KK, further comprising applying a dopant to the first channel poly layer.

Example MM includes the subject matter of Examples II to LL, further comprising applying TiN on the first channel poly layer and annealing to form a layer of a Ti silicide thereon.

Example NN includes the subject matter of Example MM, wherein the layer of the Ti silicide forms an ohmic contact to the conductive material.

Example OO includes the subject matter of Example NN, wherein the conductive material comprises at least one of Ti and W.

Example PP is directed to a method, comprising: forming a substrate comprising an arrangement of conductive source lines extending along a first direction; forming a corrugated support on the substrate, wherein the support comprises a substantially planar first major surface and an opposed second major surface, wherein the second major surface of the support comprises an array of linear ridges separated by grooves, wherein the linear ridges and grooves extend along a second direction normal to the first direction; forming an array of apertures in the support, wherein the apertures extend along a third direction normal to the first direction and the second direction, wherein the apertures each comprise an inlet region at the first major surface of the support and an outlet region in a groove in the second major surface of the support, and wherein the apertures comprise a conical region between the inlet region and the outlet region; depositing, on the first major surface of the support, tiers comprising alternating dielectric layers and nitride layers, wherein the dielectric layers and the nitride layers are substantially parallel to the first major surface and the second major surface of the support; forming openings in the tiers, wherein the openings extend along the third direction and terminate in the apertures; etching an arrangement of slits in the tiers, wherein the slits extend along the first direction and are substantially aligned with the source lines in the substrate, and wherein the slits further comprise second openings that extend through the support and form access regions overlying the grooves; depositing a channel poly material in the grooves to form a channel poly layer on walls of the openings and walls of the grooves, wherein the channel poly material is deposited in the openings in an amount sufficient to occlude the outlet regions of the apertures; etching the first channel poly layer to remove the first channel poly layer from the walls of the grooves and the walls of the outlet regions of the apertures; applying an etchant to the access regions of the slits to form passages through the substrate to the source lines; and depositing a conductive material in the grooves and the passages to form an ohmic contact between the first channel poly layer and the source lines in the substrate.

Example QQ includes the subject matter of Example PP, further comprising, prior to etching the first channel poly layer, depositing a dopant thereon.

Example RR includes the subject matter of Example QQ, wherein the depositing comprises applying a phosphorous dopant to the first channel poly layer.

Example SS includes the subject matter of Example RR, wherein the phosphorous dopant is applied to the conductive layer in an amount sufficient to form a N⁺ region in the channel poly layer.

Example TT includes the subject matter of any of Examples PP to SS, further comprising applying an oxide layer between the corrugated support and the substrate.

Example UU includes the subject matter of any of Examples PP to TT, wherein the conductive material comprises Ti and W.

Example VV includes the subject matter of any of Examples PP to UU, wherein depositing the first channel poly material comprises applying Ti and annealing to form a layer of a Ti silicide thereon.

Example WW includes the subject mattere of Example VV, wherein the layer of the Ti silicide forms an ohmic contact to the conductive material.

Example XX is directed to a method for structurally reinforcing a semiconductor device, the method comprising: forming a corrugated support on a substrate, the corrugated support comprising a planar mounting surface and a fluted region between the mounting surface and the substrate, wherein the fluted region comprises parallel ribs separated by voids, and wherein apertures in the planar mounting surface are arranged such that each aperture terminates in a void, and each aperture is reinforced by a rib on opposed sides of the void; and forming pillars on the planar mounting surface, wherein each of the pillars terminate in an aperture.

What is claimed is:

1. A semiconductor device, comprising:
a substrate comprising an arrangement of conductive interconnects;
a corrugated support on the substrate, wherein the support comprises:
a substantially planar first major surface and an opposed second major surface proximal to the substrate, the first major surface comprising a plurality of vias extending along a first direction, wherein the vias comprise an inlet at a first major surface of the support and an outlet at the second major surface of the support, and
an arrangement of flutes on the second major surface of the support, wherein the flutes extend along a second direction normal to the first direction, wherein the flutes are separated by voids, and wherein the vias terminate in the voids.

2. The semiconductor device of claim 1, wherein the vias comprise a conical region having an apex connected to the outlet.

3. The semiconductor device of claim 1, wherein the flutes comprise parallel linear ribs with a height extending along the first direction and a length extending along the second direction.

4. The semiconductor device of claim 3, wherein the voids have a trapezoidal cross-sectional shape when viewed along the second direction.

5. The semiconductor device of claim 4, wherein the ribs comprise a substantially planar plateau region proximal to the substrate.

6. The semiconductor device of claim 1, wherein the vias comprise a channel poly material in ohmic contact with a conductive material in the voids.

7. The semiconductor device of claim 6, wherein the conductive material contacts the conductive interconnects in the substrate.

8. A semiconductor device, comprising:
a support on a substrate, wherein the support comprises a substantially planar first surface and a second surface opposite the first surface, wherein the second surface comprises an array of flutes separated by voids, and wherein the flutes extend along a first direction;
tiers on the first surface of the support, the tiers comprising a stack of alternating dielectric layers and nitride layers, wherein the dielectric layers and nitride layers are arranged in planes substantially parallel to a plane of the first surface of the support; and
a plurality of openings extending through the tiers and terminating in apertures extending through the support, wherein the openings extend along a second direction normal to the first direction, and wherein the apertures are arranged such that each opening overlies a void between two adjacent flutes in the support.

9. The semiconductor device of claim 8, wherein the tiers further comprise slits extending therethrough along a third direction normal to the first direction and the second direction.

10. The semiconductor device of claim 8, wherein the flutes comprise parallel linear ribs having substantially planar top surfaces proximal to the substrate.

11. The semiconductor device of claim 8, wherein the voids have a trapezoidal cross-sectional shape when viewed along the second direction.

12. The semiconductor device of claim 8, wherein the apertures in the support comprise an inlet at the first major surface thereof and an outlet at the second major surface thereof, and a conical region between the inlet and the outlet.

13. The semiconductor device of claim 12, and wherein an apex of the conical region is proximal to the voids.

14. A method for making a semiconductor device, the method comprising:
forming a substrate comprising an arrangement of conductive source lines;
forming a support on the substrate, wherein the support has a first major surface and an opposed second major surface on the substrate, and wherein the second major surface of the support comprises a cavity;
forming an arrangement of vias extending from the first major surface to the second major surface of the support, wherein the vias terminate in the cavity;
depositing tiers comprising alternating dielectric layers and nitride layers on the first major surface of the support;
forming openings in the tiers, wherein the openings extend in a first direction normal to a plane of the support, and wherein each of the openings terminates in an aperture in the support;
depositing a channel poly material in the openings to form a first channel poly layer on walls thereof and a second channel poly layer on walls of the cavity, wherein the first channel poly layer forms a plug in a region of the opening adjacent to the cavity;
etching an arrangement of slits in the tiers, wherein the slits are aligned with the source lines in the substrate;
forming second openings in the slits, wherein the second openings in the slits form access regions to the cavity;
etching to remove the first channel poly layer and the second channel poly layer;
forming passages through the substrate to the source lines; and
depositing a conductive material in the cavity and the passages to form an ohmic contact between the first channel poly layer and the source lines in the substrate.

15. The method of claim 14, wherein the cavity comprises parallel linear channels separated by linear ribs, and wherein the ribs and channels extend in a second direction normal to the first direction.

16. The method of claim 14, further comprising applying an oxide layer between the support and the substrate.

17. The method of claim 14, further comprising applying a dopant to the first channel poly layer.

18. The method of claim 14, further comprising applying Ti on the first channel poly layer and annealing to form a layer of a Ti silicide thereon.

19. The method of claim 18, wherein the layer of the Ti silicide forms an ohmic contact to the conductive material.

20. The method of claim 19, wherein the conductive material comprises at least one of Ti and W.
